(19) United States
(12) Patent Application Publication
(10) Pub. No.: US 2026/0198244 A1
(43) Pub. Date: Jul. 9, 2026

(54) Semiconductor Device and Method of Forming Semiconductor Die with Less Back Surface Scratching

(71) Applicant: STATS ChipPAC Pte. Ltd., Singapore (SG)

(72) Inventors: Yi Jing Eric Chong, Singapore (SG); Abelardo Hadap Advincula, JR., Singapore (SG); Linda Pei Ee Chua, Singapore (SG)

(73) Assignee: STATS ChipPAC Pte. Ltd., Singapore (SG)

(21) Appl. No.: 19/010,506

(22) Filed: Jan. 6, 2025

(51) Int. Cl. H01L 23/00; H01L 21/56; H01L 21/78; H01L 23/31

(52) U.S. Cl. CPC H10P 54/00; H10W 74/014; H10W 74/111; H10W 72/0198

(57) ABSTRACT

A semiconductor device has a semiconductor wafer with a first channel formed in the semiconductor wafer and a second channel formed within the first channel to singulate the semiconductor wafer into a plurality of semiconductor die. The first channel and second channel form a T-shaped semiconductor die with a base and a stem extending from the base. A width of the stem is less than a width of the base of the T-shaped semiconductor die. The semiconductor die are disposed over a carrier as a reconstituted semiconductor wafer. An encapsulant is deposited over the reconstituted semiconductor wafer. A first portion of the encapsulant is removed to expose the stem, and a portion of the reconstituted semiconductor wafer is removed to reduce thickness of the semiconductor die. A thickness of the reconstituted semiconductor wafer is less than 100 micrometers after removing the portion of the reconstituted semiconductor wafer.

### FIELD OF THE INVENTION

The present invention relates in general to semiconductor devices and, more particularly, to a semiconductor device and method of forming a semiconductor die with less back surface scratching.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

In some applications, the semiconductor device is made as thin as practical to reduce package thickness. A rough grinding of the base semiconductor material is often used to remove large amounts of material and reduce the final thickness of the semiconductor device. The rough griding generates debris and causes scratches and grind marks on multiple sides of the back surface of the semiconductor device as the grinding wheel teeth come into contact with the back surface. The debris can cause damage to the semiconductor device surfaces.

### BRIEF DESCRIPTION OF THE DRAWINGS

FIGS. 1a-1b illustrate a semiconductor wafer with a plurality of semiconductor die separated by a saw street;

FIGS. 2a-2t illustrate a process of forming a semiconductor die with less back surface scratching;

FIGS. 3a-3b illustrate the semiconductor die having less back surface scratching from FIGS. 2a-2t;

FIGS. 4a-4d illustrate another process of forming a semiconductor die with less back surface scratching;

FIGS. 5a-5b illustrate the semiconductor die having less back surface scratching from FIGS. 4a-4d; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

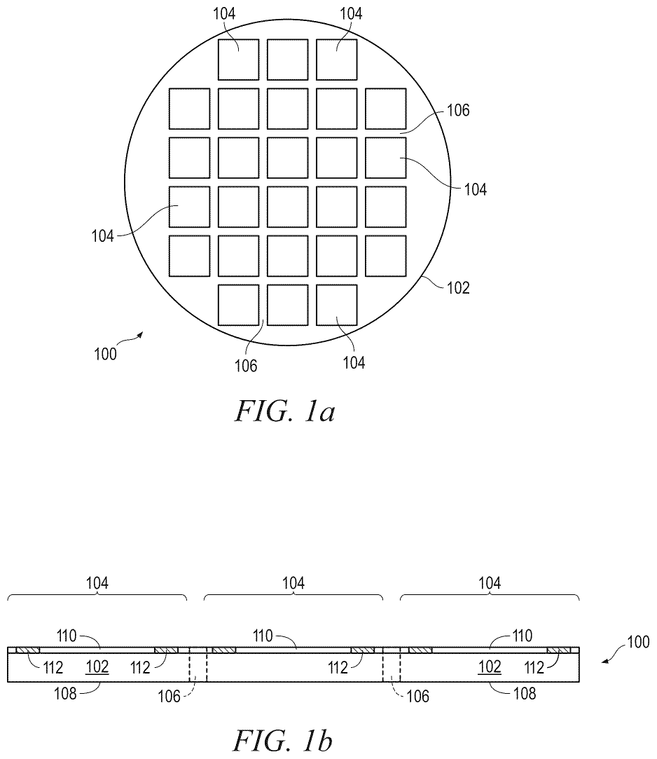

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular or any other geometric shape.

FIG. 1b shows a cross-sectional view of a portion of semiconductor wafer 100. Each semiconductor die 104 has a back or non-active surface 108 and an active layer 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over or within active layer 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits in active layer 110.

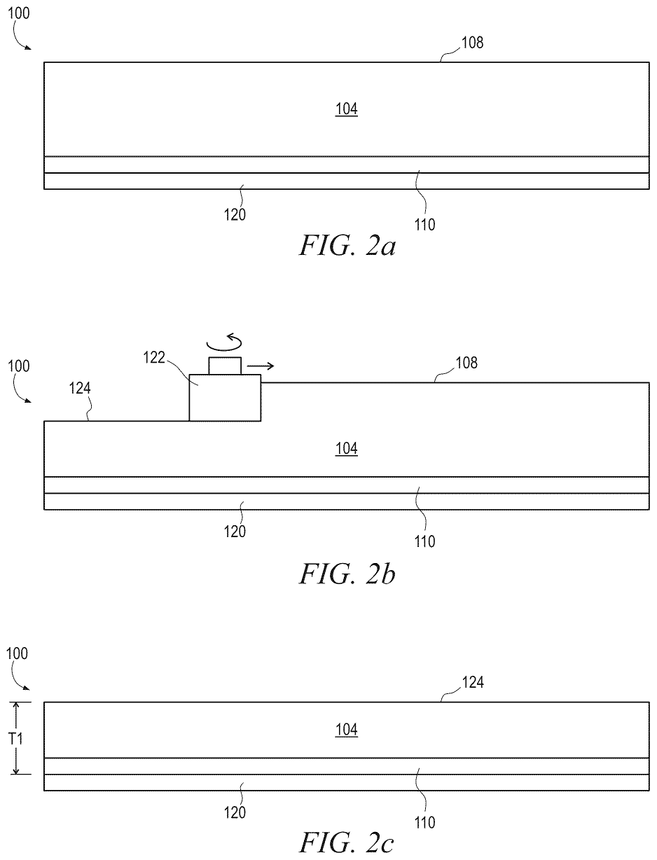

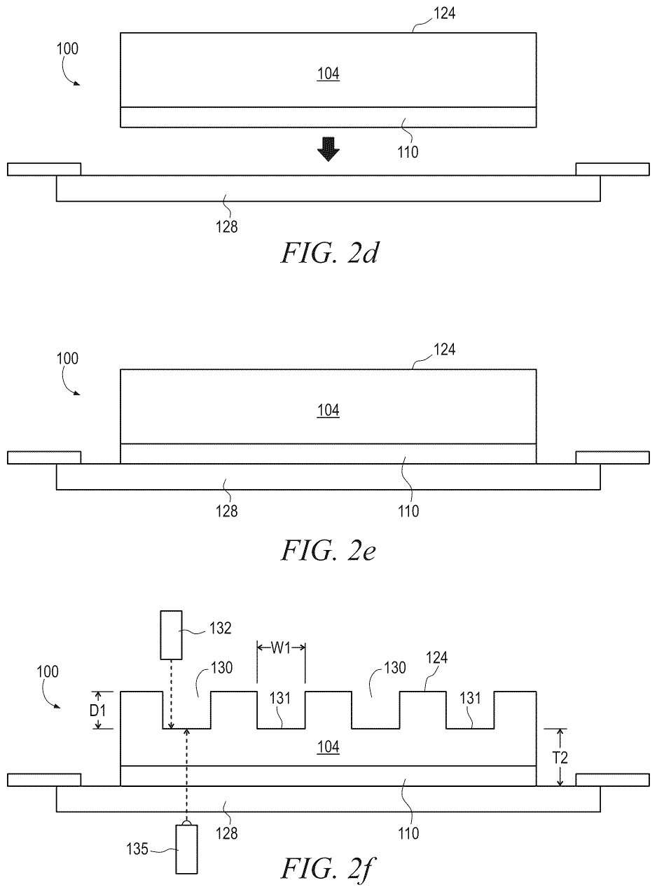

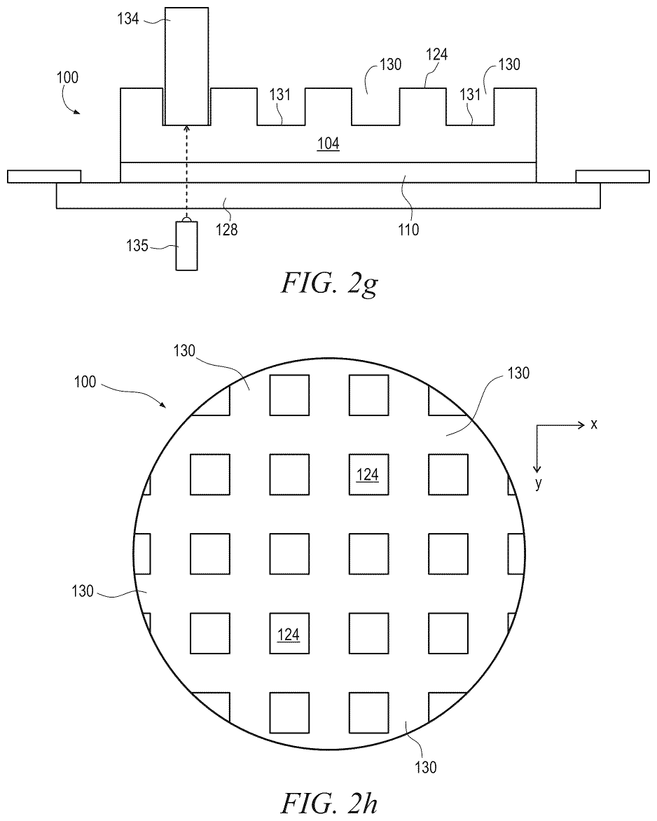

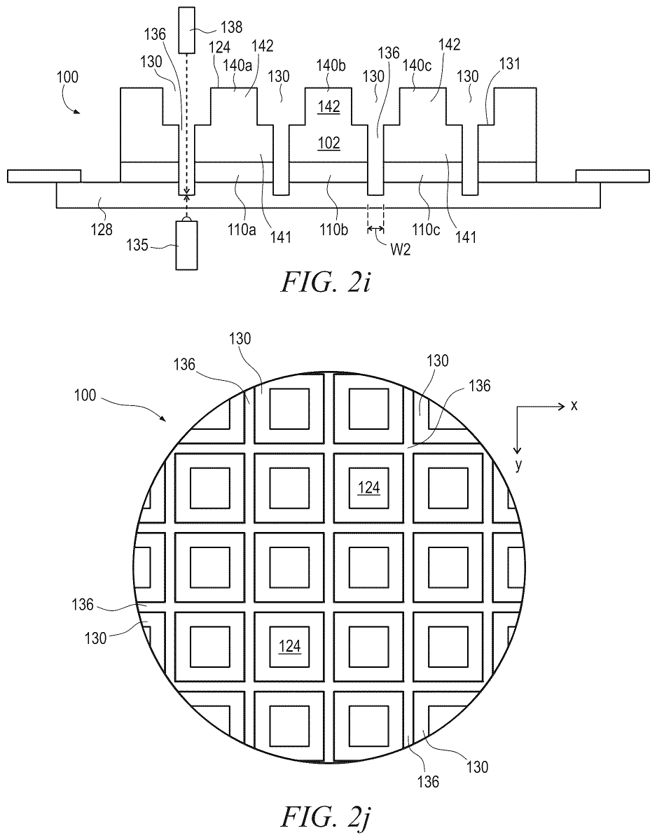

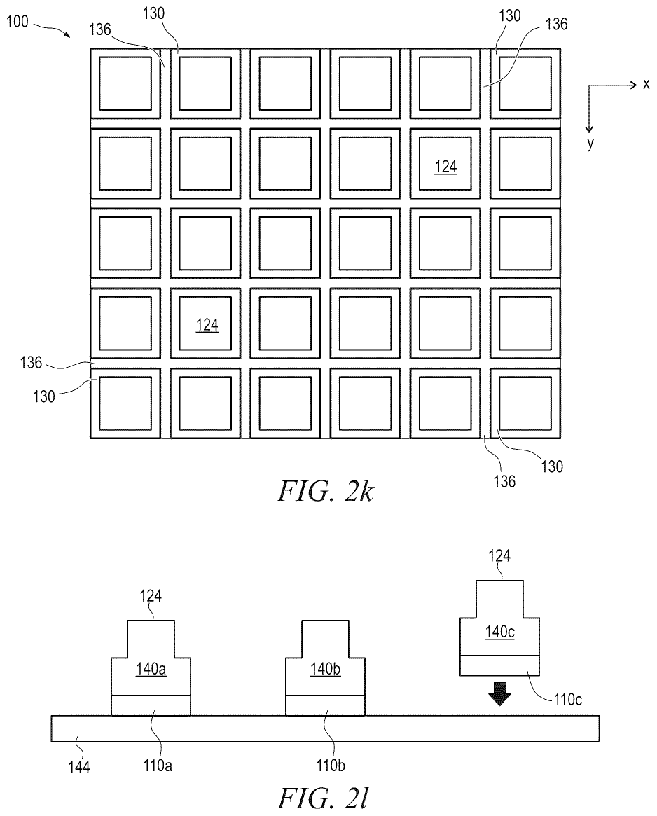

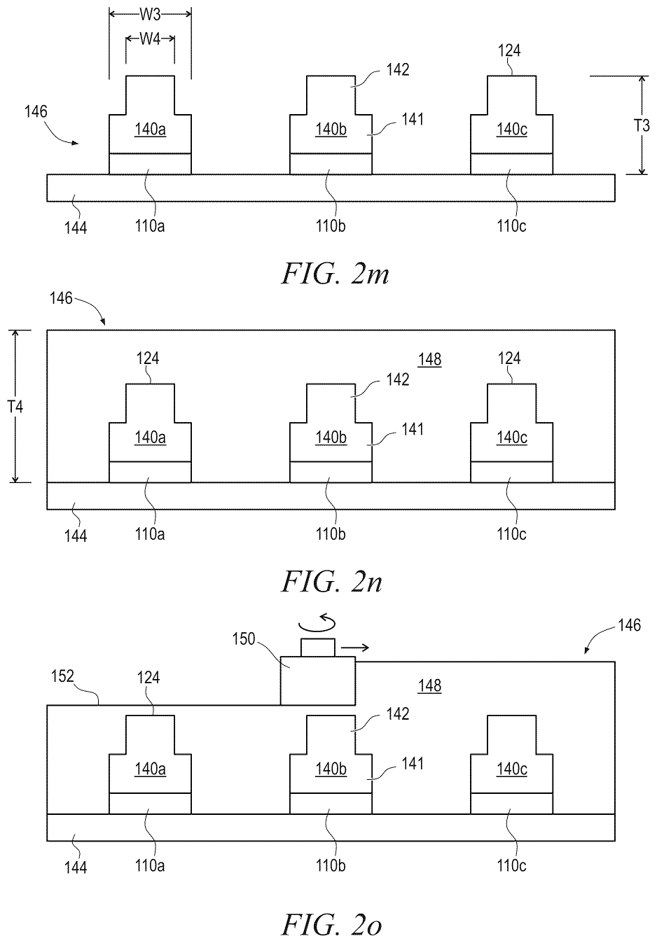

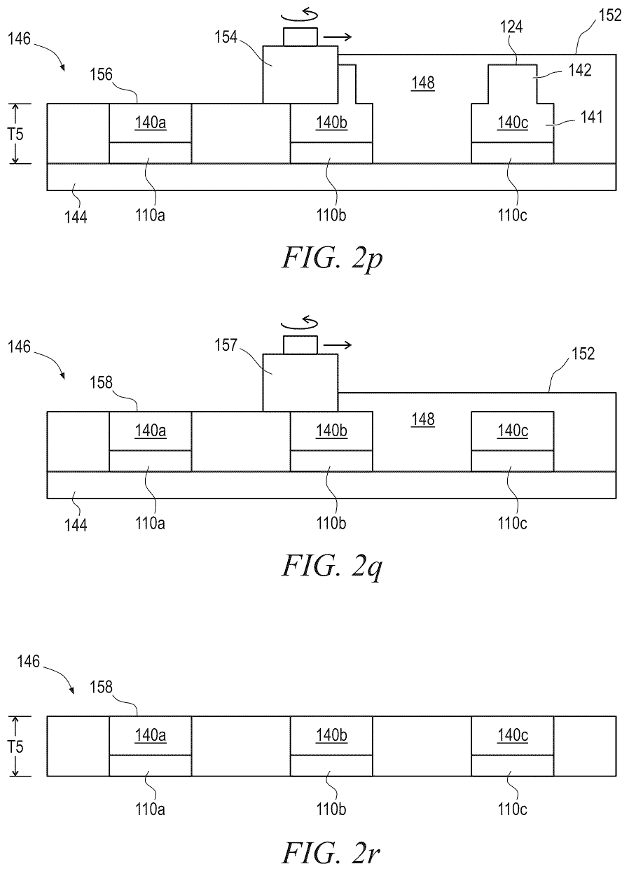

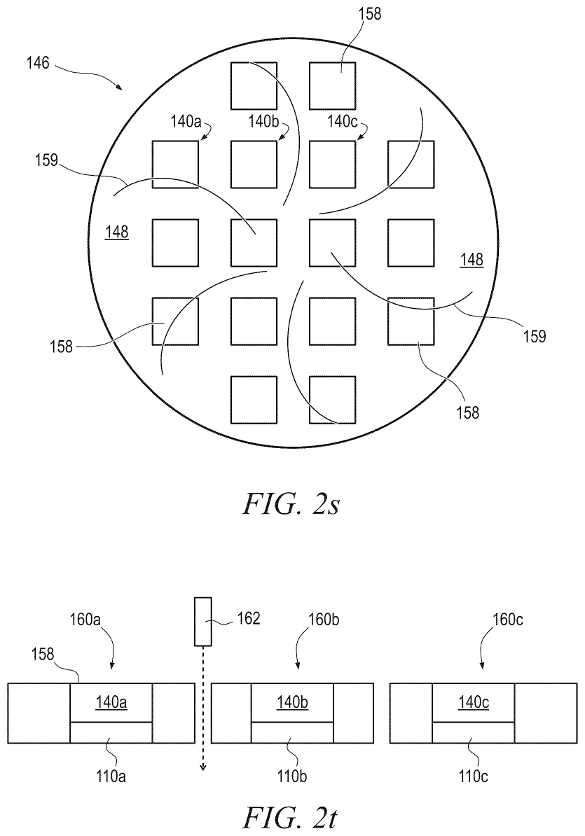

FIGS. 2a-2t illustrate a process of forming a semiconductor die with less back surface scratching. FIG. 2a shows a cross-sectional view of semiconductor wafer 100 with base semiconductor material 102 and active layer 110. Semiconductor wafer 100 is disposed on backgrinding tape 120 with active layer 110 contacting the tape. In FIG. 2b, semiconductor wafer 100 undergoes a backgrinding operation using grinder 122 to remove a portion of semiconductor material 102 down to surface 124. FIG. 2c shows semiconductor wafer 100 with post grinding surface 124. In one embodiment, the thickness T1 of semiconductor wafer 100 can be 350 micrometers (μm) post grinding.

In FIG. 2d, semiconductor wafer 100 from FIG. 2c is disposed over dicing tape 128 with active layer 110 oriented toward the tape. FIG. 2e shows semiconductor wafer 100 disposed on dicing tape 128. In FIG. 2f, a portion of semiconductor material 102 is removed to form channels 130 using laser cutting tool 132. In an alternate embodiment, a portion of semiconductor material 102 is removed to form channels 130 using saw blade 134, as shown in FIG. 2g. In one embodiment, channels 130 have a width W1 of 40-50 μm and extend to a depth D1 of 260 μm from surface 124, at least partially through semiconductor material 102. That would leave a thickness T2 of 90 μm for semiconductor wafer 100 under surface 131 at the bottom of channel 130. An infrared (IR) camera 135 provides alignment of laser cutting tool 132 or saw blade 134. Channels 130 extend in the x and y directions across back surface 108 of semiconductor wafer 100, as shown in the top view of FIG. 2h. Channels 130 are typically formed in saw streets 106 of semiconductor wafer 100 as a first step in isolating semiconductor die 104.

In FIG. 2i, another portion of semiconductor material 102 is removed to form channels 136 within channels 130 using saw blade or laser cutting tool 138 with alignment from IR camera 135. In one embodiment, channels 136 are formed in a central portion of surface 131 at the bottom of channels 130 and extend completely through the remainder of semiconductor wafer 100 and into dicing tape 128. In one embodiment, channels 136 have a width W2 of 20 μm. FIG. 2j is a top view of channels 130 and 136 for a circular semiconductor wafer 100. FIG. 2k is a top view of channels 130 and channels 136 for a rectangular semiconductor wafer 100. Note that channel 136 is formed within channel 130 and a width of channel 136 is less than a width of channel 130. Channels 130 and 136 extend in the x and y directions across back surface 108 of semiconductor wafer 100, as shown in the top view of FIGS. 2j-2k. The combination of channels 130 and channels 136 isolate and separate portions of semiconductor wafer 100 constituting semiconductor die 140a-140c into individual die.

In FIG. 2l, the individual semiconductor die 140a-140c are disposed on carrier 144 using a pick and place operation with active layer 110a-110c oriented toward the carrier. FIG. 2m shows T-shaped semiconductor die 140a-140c disposed on carrier 144 as reconstituted wafer 146. With the two cuts that form channels 130 and 136, semiconductor die 140a-140c have a T-shape with a wider base 141 with dimensions W3 of 4000 μm and a narrower stem or extended base 142 with dimensions W4 of 3000 μm. Alternatively, W4 can be made 20% of W3. Each semiconductor die 140a-140c has a corresponding active layer 110a-110c, respectively. In one embodiment, semiconductor die 140a-140c are embodied as reconstituted wafer 146 and constitute an embedded wafer level ball grid array package (eWLB).

In FIG. 2n, encapsulant 148 is deposited over reconstituted wafer 146 using a paste printing, compressive molding, transfer molding, liquid encapsulant molding, vacuum lamination, spin coating, or other suitable applicator. Encapsulant 148 can be polymer composite material, such as epoxy resin with filler, epoxy acrylate with filler, or polymer with proper filler. Encapsulant 148 is non-conductive, provides structural support, and environmentally protects the semiconductor device from external elements and contaminants. In one embodiment, encapsulant 148 has a thickness T4 of 500 μm and may extend over surface 124 by 150 μm with little or no issues as to warping or handling.

In FIG. 2o, encapsulant 148, as deposited on reconstituted wafer 146, undergoes a first backgrinding operation using grinder 150 to remove a portion of the encapsulant down to surface 152. A portion of encapsulant 148 remains covering surface 124 of semiconductor die 140a-104c. In FIG. 2p, reconstituted wafer 146 undergoes a second backgrinding operation using grinder 154 to remove a portion of encapsulant 148 and semiconductor material 102 down to surface 156. The first and second backgrinding operations are considered rough grinding, referenced as a Z1 grind, as large portions of encapsulant 148 and semiconductor material 102 are removed. In FIG. 2q, reconstituted wafer 146 undergoes a third backgrinding operation using grinder 157 to remove a portion of semiconductor material 102 down to surface 158. The third grinding is considered a fine grinding operation, referenced as a Z2 grind, removing about 20 μm of semiconductor material 102. FIG. 2r shows reconstituted wafer 146 post grinding with surface 158. Semiconductor die 160a-160c have a thickness T5 of less than 100 mm, and preferably less than 70 μm. FIG. 2s is a top view of reconstituted wafer 146 with grinding lines 159 from grinder 157. In FIG. 2t, reconstituted wafer 146 is singulated using saw blade or laser cutting tool 162 into individual semiconductor die 160a-160c.

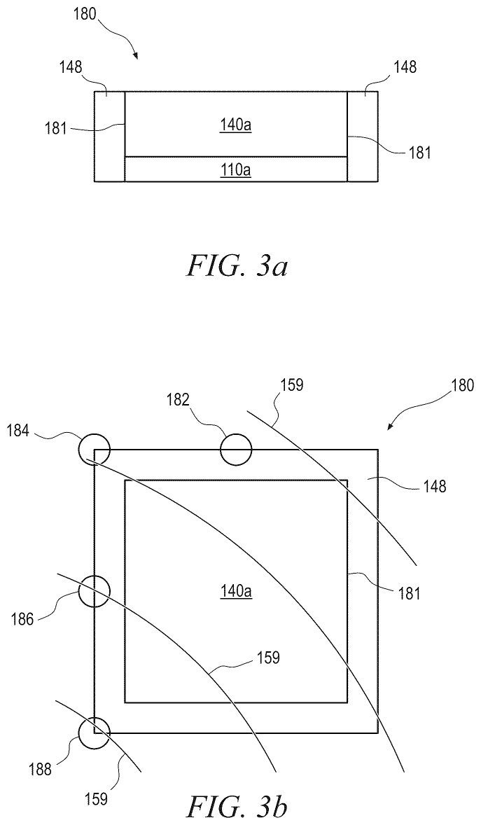

FIG. 3a is a cross-sectional view of one of semiconductor die 160a-160c and labeled as semiconductor die 180. Semiconductor die 180 may include semiconductor material 102 and active layer 110a from semiconductor die 140a. Encapsulant 148 covers at least side surface 181 of semiconductor die 180. FIG. 3b is a top view of semiconductor die 180 measuring 3.0 mm by 3.0 mm. The semiconductor die 180 produced by the process in FIGS. 2a-2t, involving at least two cuts and at least three grinding operations, reduces the need for rough grinding to remove large amounts of semiconductor material. The lesser exposed surface area of extended base 142 by nature of T-shaped semiconductor die 140a-140c during the rough grinding operations reduces grinding damage and further reduces transferred damage onto the final semiconductor die 160a-160c, particularly as back surface scratching. In other words, with smaller extended base 142, less semiconductor material 102 is exposed to the rough grinding. Grinding lines 159 at die edges 182, 184, 186, and 188 have reduced debris, chips, and other particle generation which lowers the knocking interaction between grinder wheel teeth and exposed die surfaces. With a smaller die surface area 142, there is occurrence of grind line cutting across die surface 158 and less chances of back surface scratching and other die damage.

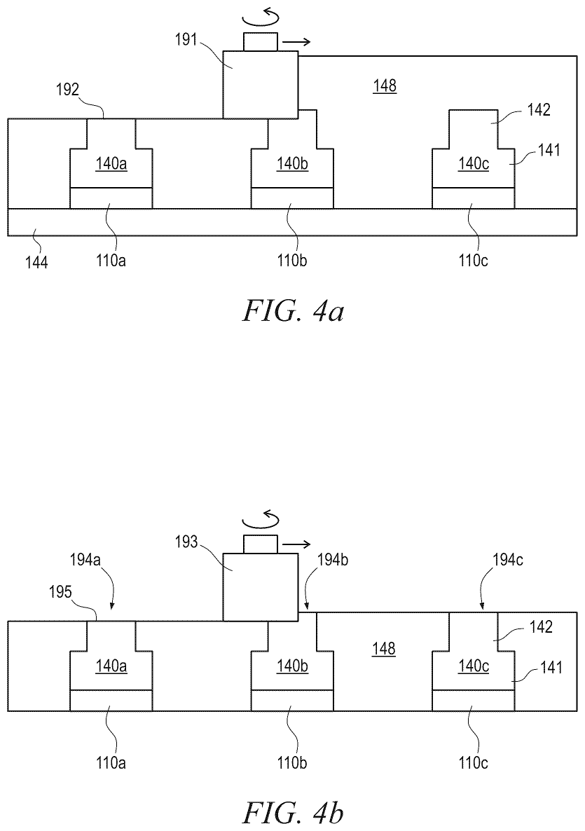

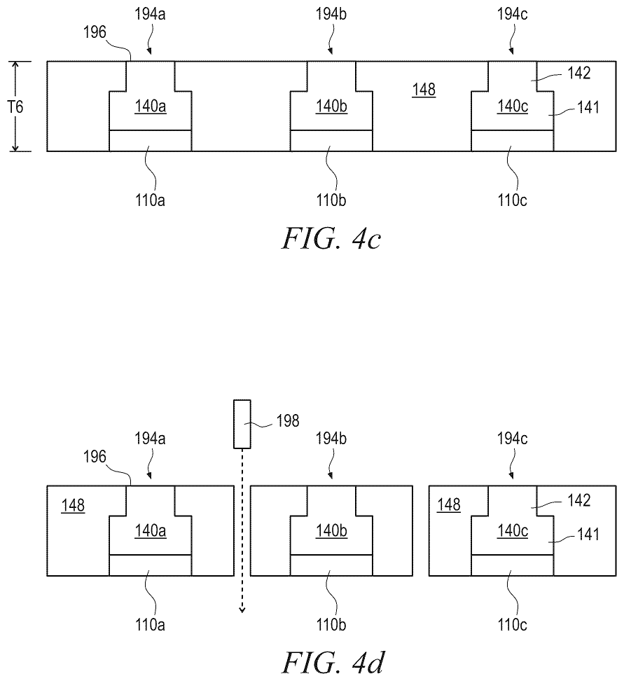

In another embodiment, reconstituted wafer 146 from FIG. 2n undergoes a rough backgrinding operation using grinder 191 to remove a portion of encapsulant 148, and possibly semiconductor material 102, down to surface 192 of the semiconductor material, as shown in FIG. 4a. Components having a similar function are assigned the same reference number. In FIG. 4b, reconstituted wafer 146 undergoes a fine backgrinding operation using grinder 193 to remove a portion of semiconductor material 102 down to surface 195. FIG. 4c shows reconstituted wafer 146 post grinding with T-shaped semiconductor die 194a-194c and associated active layers 110a-110c. Semiconductor die 160a-160c have a thickness T6 of less than 100 mm, and preferably less than 70 μm. In FIG. 4d, reconstituted wafer 146 is singulated using saw blade or laser cutting tool 198 into individual semiconductor die 194a-194c.

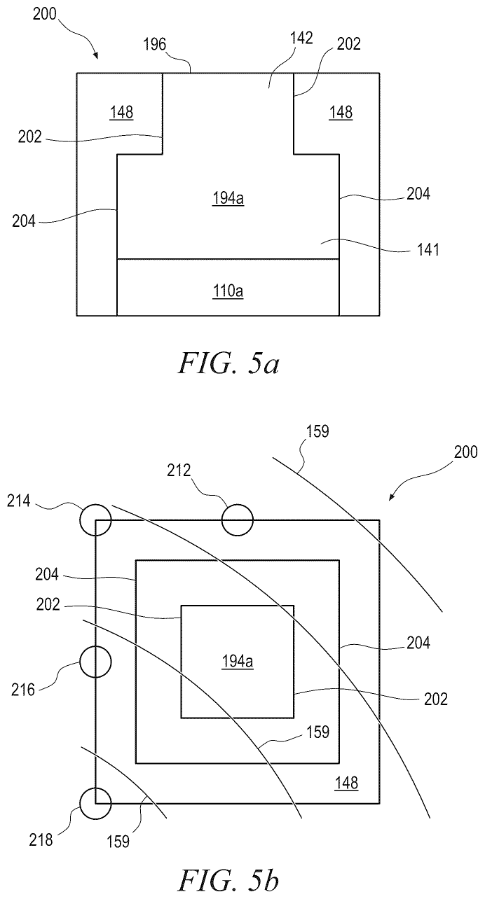

FIG. 5a is a cross-sectional view of one of semiconductor die 194a-194c, labeled as T-shaped semiconductor die 200. Semiconductor die 200 may include semiconductor material 102 and active layer 110a from semiconductor die 194a. Encapsulant 148 covers at least side surface 202 and side surface 204 of semiconductor die 200. FIG. 5b is a top view of semiconductor die 200 measuring 3.0 mm by 3.0 mm. The semiconductor die 200 produced by the process in FIGS. 2a-2n and 4a-4d involving at least two cuts and at least two grinding operations reduces the need for rough grinding to remove large amounts of semiconductor material. The lesser exposed surface area of extended base 142 by nature of T-shaped semiconductor die 160a-160c during the rough grinding operations reduces grinding damage and further reduces transferred damage onto the final semiconductor die 160a-160c, particularly as back surface scratching. Grinding lines 159 at die edges 212, 214, 216, and 218 have reduced debris, chips, and other particle generation which lowers the knocking interaction between grinder wheel teeth and exposed die surfaces. With a smaller die surface area 142, there is occurrence of grind line cutting across die surface 195 and less chances of back surface scratching and other die damage.

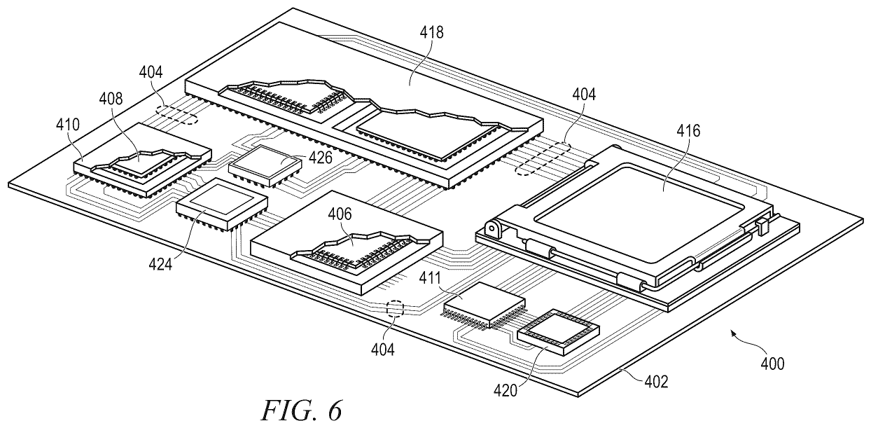

FIG. 6 illustrates electrical device 400 having a chip carrier substrate or PCB 402 with a plurality of semiconductor packages disposed on a surface of PCB 402, including semiconductor die 160a-160c and 194a-194c. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor wafer;
forming a first channel in the semiconductor wafer;
forming a second channel within the first channel to singulate the semiconductor wafer into a plurality of semiconductor die;
disposing the semiconductor die over a carrier as a reconstituted semiconductor wafer;
depositing an encapsulant over the reconstituted semiconductor wafer;
removing a first portion of the encapsulant; and
removing a portion of the reconstituted semiconductor wafer.

2. The method of claim 1, wherein the first channel and second channel form a T-shaped semiconductor die with a base and a stem extending from the base.

3. The method of claim 2, wherein removing the first portion of the encapsulant exposes the stem.

4. The method of claim 2, wherein a width of the stem is less than a width of the base of the T-shaped semiconductor die.

5. The method of claim 1, wherein a thickness of the reconstituted semiconductor wafer is less than 100 micrometers after removing the portion of the reconstituted semiconductor wafer.

6. The method of claim 1, further including removing a second portion of the encapsulant after removing the first portion of the encapsulant.

7. A method of making a semiconductor device, comprising:
forming a T-shaped semiconductor die;
disposing the T-shaped semiconductor die over a carrier as a reconstituted semiconductor substrate;
depositing an encapsulant over the reconstituted semiconductor substrate;
removing a first portion of the encapsulant; and
removing a portion of the reconstituted semiconductor substrate.

8. The method of claim 7, further including:
providing a substrate;
forming a first channel in the substrate; and
forming a second channel within the first channel to singulate the substrate into the plurality of T-shaped semiconductor die.

9. The method of claim 7, wherein the T-shaped semiconductor die includes a base and a stem extending from the base.

10. The method of claim 9, wherein removing the first portion of the encapsulant exposes the stem.

11. The method of claim 9, wherein a width of the step is less than a width of the base of the T-shaped semiconductor die.

12. The method of claim 7, wherein a thickness of the reconstituted semiconductor substrate is less than 100 micrometers after removing the portion of the reconstituted semiconductor substrate.

13. The method of claim 7, further including removing a second portion of the encapsulant after removing the first portion of the encapsulant.

14. A semiconductor device, comprising:
a semiconductor wafer including a first channel formed in the semiconductor wafer and a second channel formed within the first channel to singulate the semiconductor wafer into a plurality of semiconductor die;
a reconstituted semiconductor wafer including the semiconductor die; and
an encapsulant deposited over the reconstituted semiconductor wafer, wherein a top surface of the semiconductor die is exposed from the encapsulant.

15. The semiconductor device of claim 14, wherein the first channel and second channel form a T-shaped semiconductor die with a base and a stem extending from the base.

16. The semiconductor device of claim 15, wherein a width of the stem is less than a width of the base of the T-shaped semiconductor die.

17. The semiconductor device of claim 14, wherein a thickness of the reconstituted semiconductor wafer is less than 100 micrometers.

18. The semiconductor device of claim 14, wherein the encapsulant is disposed on a side surface of the semiconductor die.

19. The semiconductor device of claim 14, wherein a width of the first channel is W1 and a width of the second channel is W2.

20. A semiconductor device, comprising:
a T-shaped semiconductor die;
a reconstituted semiconductor wafer including the T-shaped semiconductor die; and
an encapsulant deposited over the reconstituted semiconductor substrate, wherein a top surface of the semiconductor die is exposed from the encapsulant.

21. The semiconductor device of claim 20, wherein T-shaped semiconductor die include a base and a stem extending from the base.

22. The semiconductor device of claim 21, wherein a width of the stem is less than a width of the base of the T-shaped semiconductor die.

23. The semiconductor device of claim 20, wherein a thickness of the reconstituted semiconductor substrate is less than 100 micrometers.

24. The semiconductor device of claim 20, wherein the encapsulant is disposed on a side surface of the semiconductor die.

25. The semiconductor device of claim 20, wherein a width of the first channel is W1 and a width of the second channel is W2.
